(19) United States
(12) Patent Application Publication
(10) Pub. No.: US 2026/0059836 A1
(43) Pub. Date: Feb. 26, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventors: Kyung Jin LEE, Icheon-si Gyeonggi-do (KR); Ji Yeon BAEK, Icheon-si Gyeonggi-do (KR); Sang Hwan CHOI, Icheon-si Gyeonggi-do (KR); Jae Deok KIM, Icheon-si Gyeonggi-do (KR); Yong Hee WOO, Icheon-si Gyeonggi-do (KR); Hyun Jo LEE, Icheon-si Gyeonggi-do (KR)

(73) Assignee: SK hynix Inc., Icheon-si Gyeonggi-do (KR)

(21) Appl. No.: 18/954,061

(22) Filed: Nov. 20, 2024

(30) Foreign Application Priority Data
Aug. 21, 2024 (KR) 10-2024-0111959

(51) Int. Cl. H01L 29/423; H01L 21/28; H01L 29/417; H01L 29/66

(52) U.S. Cl. CPC H10D 64/517; H01L 21/28132; H10D 64/021; H10D 64/258

(57) ABSTRACT

A semiconductor device may include: a gate structure including a plurality of conductive layers alternately stacked with a plurality of insulating layers; a source contact structure extending through the gate structure; a nitride spacer surrounding a first end of the source contact structure; and an oxide spacer surrounding the nitride spacer and a second end of the source contact structure.

### CROSS-REFERENCE TO RELATED APPLICATION

The present application claims priority under 35 U.S. C. § 119(a) to Korean Patent Application No. 10-2024-0111959, filed in the Korean Intellectual Property Office on Aug. 21, 2024, which application is incorporated herein by reference in its entirety.

### BACKGROUND

### 1. Technical Field

The present disclosure relates to electronic devices, including but not limited to a semiconductor device and a method of manufacturing the semiconductor device.

### 2. Related Art

The degree of integration of a semiconductor device is mainly determined by an area occupied by a unit memory cell. As improvement in the degree of integration of a semiconductor device in a single layer on a substrate reaches a limit of forming memory cells, a three-dimensional semiconductor device that stacks memory cells on a substrate is under development. To improve the operational reliability of such a semiconductor device, various structures and manufacturing methods are also under development.

### SUMMARY

In an embodiment, a semiconductor device may include: a gate structure including a plurality of conductive layers alternately stacked with a plurality of insulating layers; a source contact structure extending through the gate structure; a nitride spacer surrounding a first end of the source contact structure; and an oxide spacer surrounding the nitride spacer and a second end of the source contact structure.

In an embodiment, a semiconductor device may include: a source structure; a gate structure located over the source structure and including a plurality of conductive layers alternately stacked with a plurality of insulating layers; a source contact structure extending into the source structure through the gate structure; a first nitride spacer located in the gate structure and surrounding a first end of the source contact structure; a second nitride spacer located in the source structure, surrounding a second end of the source contact structure, and spaced apart from the first nitride spacer; and an oxide spacer extending along the sidewall of the source contact structure and surrounding the first nitride spacer and the second nitride spacer.

In an embodiment, a method of manufacturing a semiconductor device may include: forming a stack including a plurality of first material layers alternately stacked with a plurality of second material layers; forming an opening extending through the stack; forming an oxide liner within the opening; forming a nitride liner along a surface of the oxide liner; forming a nitride spacer by etching the nitride liner such that the oxide liner is partially exposed; forming an oxide spacer by etching the oxide liner, the oxide spacer extending along the inner wall of the stack and surrounding the nitride spacer; and forming a source contact structure within the nitride spacer and the oxide spacer.

In an embodiment, a method of manufacturing a semiconductor device may include: forming a stack over a source structure; forming an opening extending into the source structure through the stack; forming an oxide liner within the opening; forming a nitride liner along a surface of the oxide liner; forming a first nitride spacer and a second nitride spacer by etching the nitride liner, the second nitride spacer located in the source structure and spaced apart from the first nitride spacer; and forming an oxide spacer by etching the oxide liner, the oxide spacer surrounding the first nitride spacer and the second nitride spacer.

### BRIEF DESCRIPTION OF THE DRAWINGS

FIG. 1 is a diagram illustrating the structure of a semiconductor device in accordance with an embodiment.

FIG. 2 is a diagram illustrating the structure of a semiconductor device in accordance with an embodiment.

FIG. 3A to FIG. 3F are cross-sectional views illustrating a semiconductor device as formed utilizing a method of manufacturing a semiconductor device in accordance with an embodiment.

FIG. 4A to FIG. 4H are cross-sectional views illustrating a semiconductor device as formed utilizing a method of manufacturing a semiconductor device in accordance with an embodiment.

### DETAILED DESCRIPTION

Various embodiments are directed to a semiconductor device having a stable structure and improved reliability as well as other characteristics and a method of manufacturing the semiconductor device.

By stacking memory cells in three dimensions, the degree of integration of a semiconductor device may be improved. A semiconductor device having a stable structure and improved reliability may result.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

When one element is identified as “connected” to another element, the elements may be connected directly or through an intervening element between the elements. When two elements are identified as “directly connected,” one element is directly connected to the other element without an intervening element between the two elements. Terms such as “bottom,” “below,” “over,” “inside,” “upper,” “uppermost,” “lower,” “lowermost,” “high,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

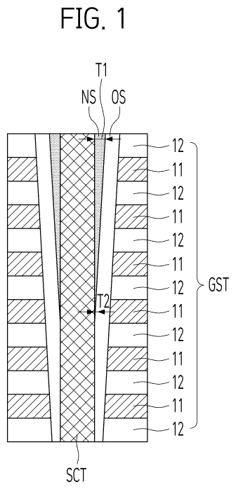

FIG. 1 is a diagram illustrating the structure of a semiconductor device in accordance with an embodiment.

Referring to FIG. 1, the semiconductor device includes a gate structure GST, a source contact structure SCT, a nitride spacer NS, and an oxide spacer OS.

The gate structure GST include conductive layers 11 alternately stacked with insulating layers 12. The conductive layers 11 may be gate lines such as a source select line, word lines, or a drain select line. The conductive layers 11 include a first set of conductive layers 11 located at a first end or an uppermost end of the conductive layers 11 of the gate structure GST and a second set of conductive layers 11 located at a second end or a lowermost end of the conductive layers 11 of the gate structure GST. For example, the second set of conductive layers 11 includes at least one conductive layer 11 located at the lowermost end of the conductive layers 11 may be a source select line, the first set of conductive layers 11 includes at least one conductive layer 11 located at the uppermost end of the conductive layers 11 may be a drain select line, and the other conductive layers 11 of the first set and the second set may be word lines. The conductive layers 11 include a conductive material such as polysilicon or metal. The insulating layers 12 insulate the stacked conductive layers 11 from each other and may include oxide, nitride, air gap, or the like.

The source contact structure SCT extends through the gate structure GST. The source contact structure SCT includes a conductive material such as polysilicon or metal and may have a single-layer or multilayer structure. The first set of conductive layers 11 may surround a first end the source contact structure, and the first set of the conductive layers 11 may surround a second end of the source contact structure.

The nitride spacer NS surrounds a first end of the source contact structure SCT, such as an upper sidewall of the source contact structure SCT. The second set of the conductive layers 11 do not surround the nitride spacer NS. For example, the second set of conductive layers 11 includes at least one conductive layer 11 located at the lowermost end of the conductive layers 11 and does not surround the nitride spacer NS, and the first set of conductive layers 11 surrounds the nitride spacer NS. The second set of conductive layers 11 that do not surround the nitride spacer NS may include a source select line and/or word lines, and the first set of conductive layers 11 that surrounds the nitride spacer NS may include word lines and/or a drain select line.

The nitride spacer NS extends along an inner surface of the oxide spacer OS and has different thicknesses at different locations along the inner surface, for example, due to a tapered shape. The nitride spacer NS may have a second thickness T2 at a second end or lower end, which thickness T2 is narrower than a first thickness T1 at first end or an upper end. The nitride spacer NS may have a shape with a thickness that decreases toward the bottom of the nitride spacer NS.

The oxide spacer OS surrounds the nitride spacer NS and lower sidewalls or the second end of the source contact structure SCT. The oxide spacer OS contacts the outer walls of the nitride spacer NS and the lower sidewalls of the source contact structure SCT.

A portion of the sidewall of the source contact structure SCT is surrounded by the nitride spacer NS and the oxide spacer OS, and the remainder of the sidewall of the source contact structure SCT is surrounded by the oxide spacer OS and not the nitride spacer NS. During a manufacturing process, hydrogen ions or a fluorine gas may move or pass through the portion of the source contact structure SCT that is not surrounded by the nitride spacer NS. Accordingly, the source contact structure SCT may be used as a passageway for hydrogen passivation and fluorine outgassing, and the reliability of the semiconductor device may be improved.

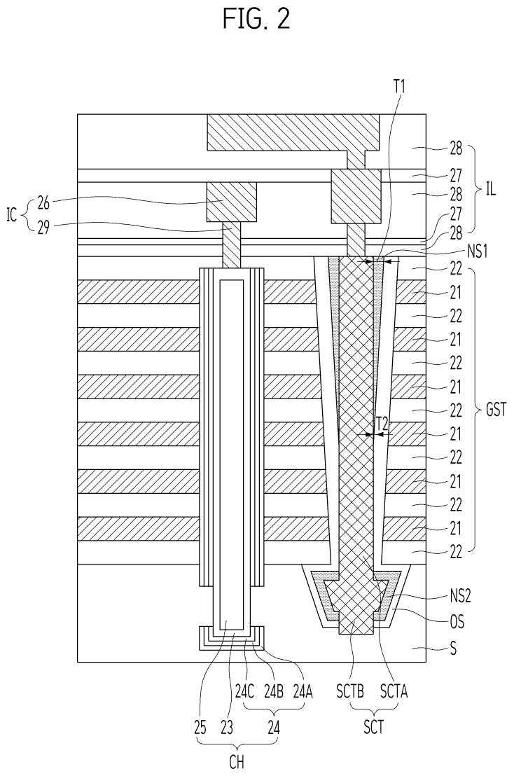

FIG. 2 is a diagram illustrating the structure of a semiconductor device in accordance with an embodiment.

Referring to FIG. 2, the semiconductor device includes a source structure S, a gate structure GST, a source contact structure SCT, a first nitride spacer NS1, a second nitride spacer NS2, and an oxide spacer OS. The semiconductor device in the example of FIG. 2 further includes at least one of a channel structure CH, an interlayer insulating layer IL, and an interconnection structure IC.

The gate structure GST includes conductive layers 21 alternately stacked with insulating layers 22. The conductive layers 21 are gate lines such as a source select line, word lines, or a drain select line. The conductive layers 21 include a conductive material such as polysilicon or metal. The insulating layers 22 insulate consecutive conductive layers 21 from each other and may include oxide, nitride, air gap, or the like.

The source structure S is located below the gate structure GST. The source structure S includes a conductive material such as polysilicon or metal. The source structure S may be a single layer or multilayer structure. For example, the source structure S may include multilayer polysilicon layers.

The channel structure CH extends through the gate structure GST and is connected to the source structure S. The channel structure CH includes a channel layer 23, a memory layer 24 surrounding the channel layer 23, and an insulating core 25 located within the channel layer 23. The memory layer 24 includes a blocking layer 24A, a data storage layer 24B, and a tunneling layer 24C. The data storage layer 24B may include a floating gate, polysilicon, a charge trap material, nitride, a variable resistance material, or the like. The source structure S may extend through the memory layer 24 and directly connect to the channel layer 23.

The source contact structure SCT extends into the source structure S through the gate structure GST. The source contact structure SCT includes a through-segment SCTA and an extension SCTB. The through-segment SCTA extends through the gate structure GST. The extension SCTB is connected to the through-segment SCTA. The source contact structure SCT is formed as a single structure including the extension SCTB as well as the through-segment SCTA physically connected or coupled to the extension SCTB. The extension SCTB is located within the source structure S. The extension SCTB has a greater width than the through-segment SCTA. For example, at the intersection where the through-segment SCTA joins the extension SCTB, the extension SCTB has a greater width than the through-segment SCTA.

The first nitride spacer NS1 surrounds upper sidewalls of the through-segment SCTA and does not surround lower sidewalls of the through-segment SCTA and does not surround sidewalls of the extension SCTB. The conductive layers 21 include a first set of conductive layers 21 located at a first end or an uppermost end of the gate structure GST and a second set of conductive layers 21 located at a second end or a lowermost end of the gate structure GST. The second set of the conductive layers 21 do not surround the first nitride spacer NS1. For example, the second set of the conductive layers 21 includes at least one conductive layer 21 located at the lowermost end of the conductive layers 21 does not surround the first nitride spacer NS1, and the first set of conductive layers 21 surrounds the first nitride spacer NS1. The second set of conductive layers 21 that do not surround the first nitride spacer NS1 include, for example, a source select line or word lines, and the first set of conductive layers 21 that surround the first nitride spacer NS1 include, for example, word lines and/or a drain select line.

The first nitride spacer NS1 extends along an inner surface of the oxide spacer OS and has different thicknesses at different locations along the inner surface, for example, due to a tapered shape. The first nitride spacer NS1 may have a second thickness T2 at a second end or lower end, which thickness is narrower than a first thickness T1 at first end or an upper end. The first nitride spacer NS1 may have a shape with a thickness that decreases toward the bottom of the nitride spacer NS1.

The second nitride spacer NS2 surrounds the extension SCTB and does not surround the through-segment SCTA. The second nitride spacer NS2 is spaced apart from the first nitride spacer NS1.

The oxide spacer OS surrounds the source contact structure SCT and the first nitride spacer NS1 and the second nitride spacer NS2 are disposed between the oxide spacer OS and the source contact structure SCT. The oxide spacer OS extends along sidewalls of the source contact structure SCT and surrounds the first nitride spacer NS1 and the second nitride spacer NS2. The oxide spacer OS contacts outer walls of the first nitride spacer NS1 and contacts outer walls of the second nitride spacer NS2. Between the first nitride spacer NS1 and the second nitride spacer NS2, the oxide spacer OS contacts the source contact structure SCT.

The interlayer insulating layer IL is located over the gate structure GST at a first end of the gate structure GST. The interlayer insulating layer IL may be a single-layer or a multilayer structure. For example, the interlayer insulating layer IL includes etch stop layers 27 alternately stacked with insulating layers 28. The etch stop layer 27 includes a material having a high etch selectivity with respect to the etch selectivity of the insulating layer 28. For example, the etch stop layer 27 may include nitride, and the insulating layer 28 may include high density plasma (HDP) oxide.

The interconnection structure IC is located within the interlayer insulating layer IL and includes at least one via 29 and at least one wiring line 26. For example, the wiring line 26 includes a bit line connected to the channel structure CH.

Sections of the sidewall of the source contact structure SCT are surrounded by one of the first nitride spacer NS1 and the second nitride spacer NS2 and another section of the source contact structure SCT is surrounded by the oxide spacer OS and neither of the nitride spacers NS1 and NS2. During a manufacturing process, hydrogen ions or a fluorine gas may move or pass through the section of the source contact structure SCT that is not surrounded by the first nitride spacer NS1 and that is not surrounded by the second nitride spacer NS2.

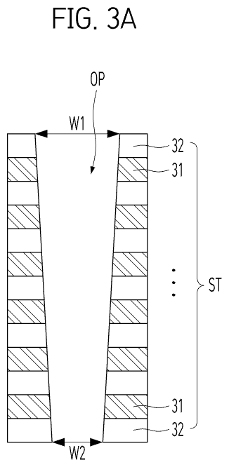

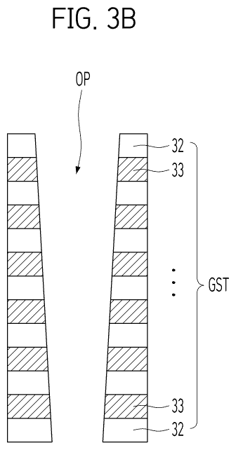

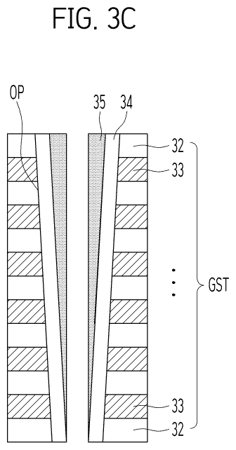

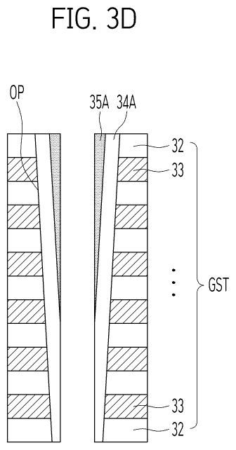

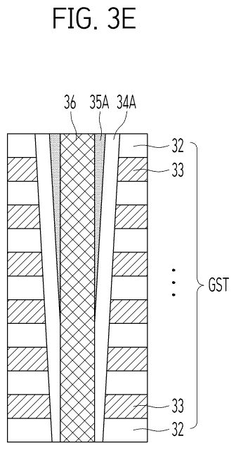

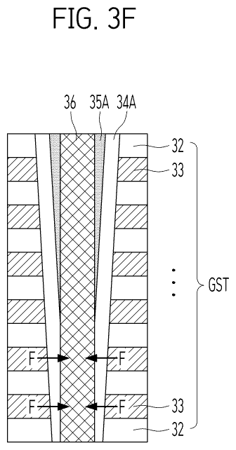

FIG. 3A to FIG. 3F are cross-sectional views illustrating a semiconductor device as formed utilizing a method of manufacturing a semiconductor device in accordance with an embodiment.

Referring to FIG. 3A, a stack ST is formed. The stack ST includes first material layers 31 alternately stacked with second material layers 32. The first material layers 31 include a material having a high etching selectivity with respect to the second material layers 32. The first material layers 31 form gate lines and include a sacrificial material such as nitride or a conductive material such as polysilicon or metal. The second material layers 32 insulate consecutive gate lines from each other and may include oxide, nitride, air gap, or the like.

An opening OP is formed in the stack ST. The opening OP extend through the stack ST. The opening OP has an upper width W1 different from a lower width W2. For example, the lower width W2 may be narrower than the upper width W1. The opening OP may have a cross section that is tapered, bowed shape, or the like.

Referring to FIG. 3B, the first material layers 31 are replaced with third material layers 33 through the opening OP. A gate structure GST is formed including the third material layers 33 alternately stacked with the second material layers 32. The third material layers 33 form gate lines and may include metal such as tungsten or molybdenum. The third material layers 33 may include a gas. For example, a source gas may be used during a process of replacing the first material layers 31 with the third material layers 33 and may remain within the third material layers 33. The source gas may be a fluorine gas.

Referring to FIG. 3C, an oxide liner 34 is formed in the opening OP. The oxide liner 34 is formed along an inner surface of the gate structure GST exposed through the opening OP and may be formed at a substantially uniform thickness. For example, the oxide liner 34 may be deposited using an atomic layer deposition (ALD) method having excellent or good step coverage. The oxide liner 34 may be formed with a thickness of 400 Å to 500 Å.

A nitride liner 35 is formed on or within the oxide liner 34. The nitride liner 35 is formed along a surface of the oxide liner 34 and may have different thicknesses at different locations along the surface of the oxide liner 34, for example, due to a tapered shape. The nitride liner 35 may have a greater thickness at an upper end of the opening OP than at a lower end of the opening OP. The nitride liner 35 may have a tapered shape. The nitride liner 35 may be deposited by a method having poor or inferior step coverage compared to the method utilized to deposit the oxide liner 34. For example, the nitride liner 35 may be deposited using a chemical vapor deposition (CVD) method having inferior step coverage to the ALD method. The nitride liner 35 may be formed with a narrower thickness than the thickness of the oxide liner 34. The nitride liner 35 may be formed with a thickness of 120 Å to 150 Å.

Referring to FIG. 3D, a nitride spacer 35A is formed by etching the nitride liner 35. The nitride liner 35 is etched such that the oxide liner 34 is exposed within the opening OP. For example, the opening OP may have a narrower width at the lower end than at the upper end, and an end of the nitride liner 35 located at the lower end of the opening OP may be etched first. Accordingly, the oxide liner 34 is exposed at a lower end of the opening OP, and the nitride spacer 35A is formed at an upper end of the opening OP. The nitride spacer 35A may be formed to avoid covering at least one third material layer 33 located at the lowermost end of the gate structure GST.

A thickness and a height of the nitride spacer 35A may be adjusting by adjusting an etching time of the nitride liner 35. As the etching time increases, the height or length of the nitride spacer 35A decreases, and the quantity of third material layers 33 that are not covered by the nitride spacer 35A increases.

The oxide liner 34 is exposed during the process of forming the nitride spacer 35A, and the exposed oxide liner 34 is etched. An oxide spacer 34A extending along the inner walls of the gate structure GST exposed through the opening OP and surrounding the nitride spacer 35A is formed by etching the oxide liner 34.

Referring to FIG. 3E, a source contact structure 36 is formed in the opening OP. The source contact structure 36 includes a conductive material such as polysilicon or metal. The nitride spacer 35A surrounds upper sidewalls of the source contact structure 36. The oxide spacer 34A surrounds the nitride spacer 35A and lower sidewalls of the source contact structure 36. For example, the oxide spacer 34A contacts outer walls of the nitride spacer 35A and contacts the lower sidewalls of the source contact structure 36.

Referring to FIG. 3F, an annealing process is performed. For example, the annealing process may be performed at a temperature of 500° C. to 700° C. to release the gas in the third material layers 33. The oxide spacer 34A and the nitride spacer 35A may have different gas permeabilities. The gas permeability of the nitride spacer 35A may be lower than the gas permeability of the oxide spacer 34A. Accordingly, the nitride spacer 35A is a diffusion barrier or an outgassing barrier blocking the release of gas.

The gas in the third material layers 33 is diffused away from the nitride spacer 35A. Because the lower sidewalls of the source contact structure 36 are not surrounded by the nitride spacer 35A, the gas is diffused into a lower end of the source contact structure 36 through the oxide spacer 34A. The gas diffused into the source contact structure 36 may be released or trapped in the source contact structure 36.

According to the manufacturing method, the gas in the third material layers 33 moves into the source contact structure 36 through the oxide spacer 34A. By releasing the gas in the third material layers 33, damage to the surrounding layers due to fumes may be reduced.

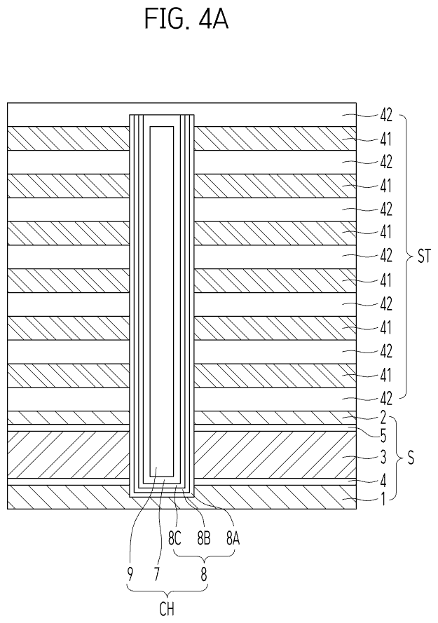

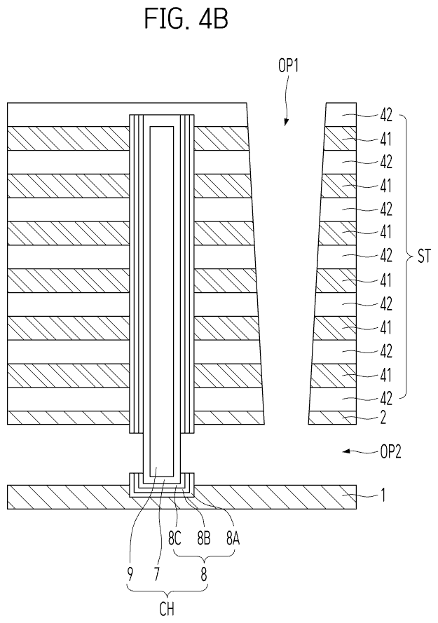

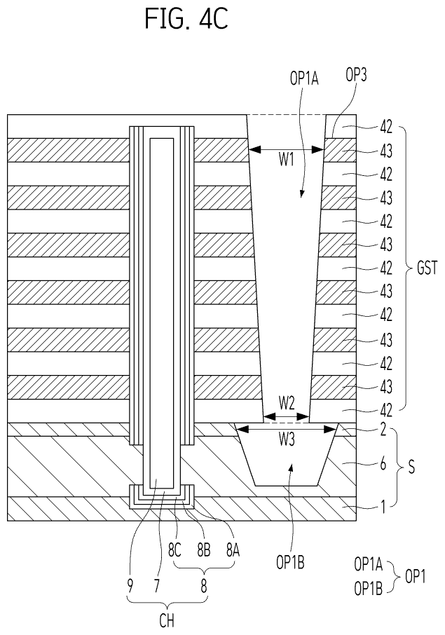

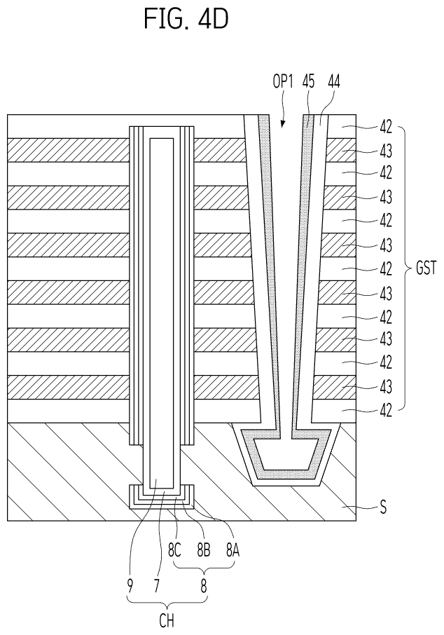

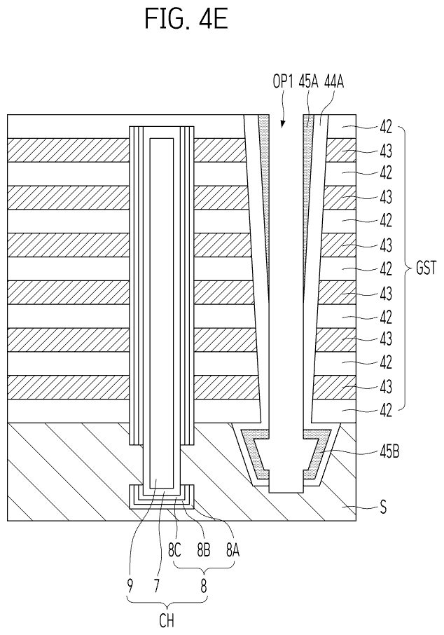

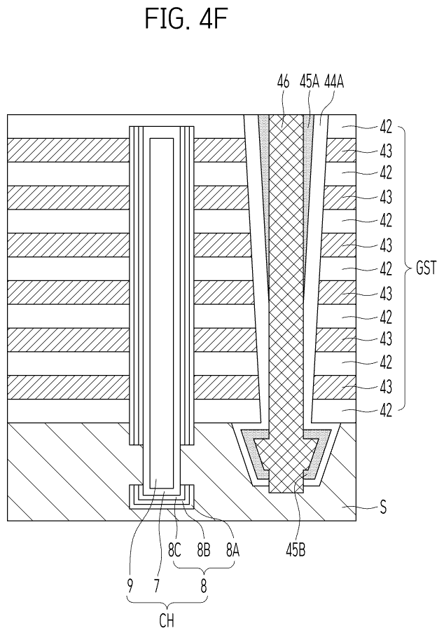

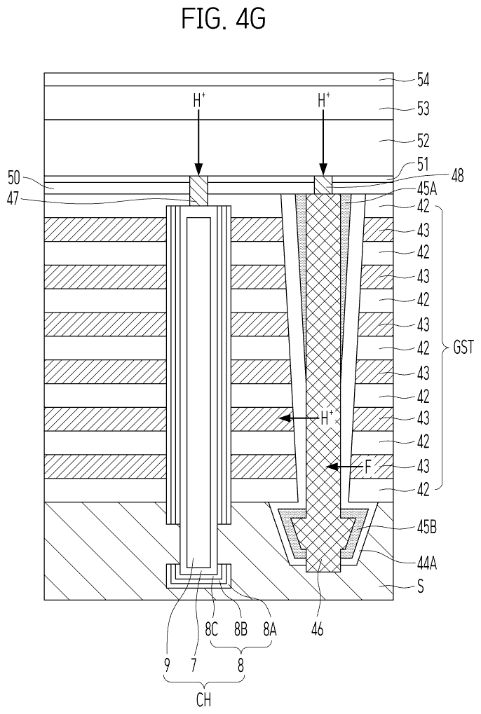

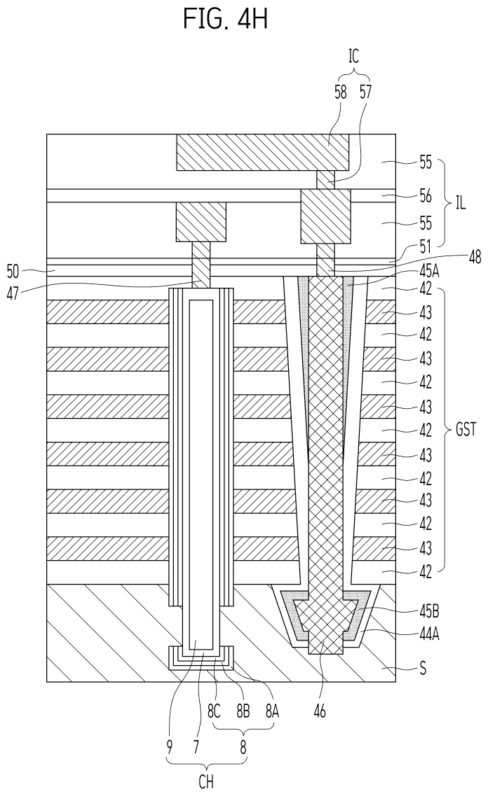

FIG. 4A to FIG. 4H are cross-sectional views illustrating a semiconductor device as formed utilizing a method of manufacturing a semiconductor device in accordance with an embodiment.

Referring to FIG. 4A, a source structure S is formed. The source structure S is a multilayer structure including a sacrificial layer 3. For example, the source structure S includes a first source layer 1, a second source layer 2, and the sacrificial layer 3 located between the first source layer 1 and the second source layer 2. The source structure S includes a first buffer layer 4 located between the first source layer 1 and the sacrificial layer 3 and a second buffer layer 5 located between the sacrificial layer 3 and the second source layer 2. The first buffer layer 4 and the second buffer layer 5 include a material having a high etching selectivity with respect to the etching selectivity of the sacrificial layer 3. For example, the sacrificial layer 3 includes polysilicon, and the first buffer layer 4 and the second buffer layer 5 include oxide. The first source layer 1 and the second source layer 2 may include polysilicon.

A stack ST is formed over the source structure S. The stack ST includes first material layers 41 alternately stacked with second material layers 42. The first material layers 41 include a material having a high etching selectivity with respect to the etching selectivity of the second material layers 42. The first material layers 41 form gate lines and include a sacrificial material such as nitride or a conductive material such as polysilicon or metal. The second material layers 42 insulate consecutive stacked gate lines from each other and may include oxide, nitride, air gap, or the like.

A channel structure CH extending into the source structure S through the stack ST is formed. The channel structure CH includes a channel layer 7, a memory layer 8 surrounding the channel layer 7, and an insulating core 9 located within the channel layer 7. Subsequent to forming the channel structure CH, a second material layer 42 may be formed on the stack ST.

Referring to FIG. 4B, a first opening OP1 is formed in the stack ST. The first opening OP1 extends into the source structure S through the stack ST. The first opening OP1 is formed to a depth that exposes the sacrificial layer 3. A second opening OP2 is formed by removing the sacrificial layer 3. Before the sacrificial layer 3 is removed, a protective layer may be formed on inner walls of the first opening OP1. The protective layer may include a material having a high etching selectivity with respect to the etching selectivity of the sacrificial layer 3.

The memory layer 8 exposed through the second opening OP2 is etched. During a process of etching the memory layer 8, the first buffer layer 4 and the second buffer layer 5 are removed. As the memory layer 8 is removed, the channel layer 7 is exposed.

Referring to FIG. 4C, a third source layer 6 is formed in the second opening OP2. For example, the third source layer 6 is formed in the second opening OP2 by forming a source material layer in the first opening OP1 and the second opening OP2 and etching the source material layer. The third source layer 6 may be directly connected to the channel layer 7. A source structure S including the first source layer 1, the second source layer 2, and the third source layer 6 is formed.

The first opening OP1 extends into the source structure S through the stack ST. The first opening OP1 includes a first aperture OP1A located inside the stack S and a second aperture OP1B located inside the source structure S. The first aperture OP1A has a lower width W2 narrower than an upper width W1. The width of the second aperture OP1B is wider than the width of the first aperture OP1A where the first aperture OP1A and the second aperture OP1B meet. At the intersection where the first portion OP1A joins the second portion OP1B, the second aperture OP1B has a width W3 wider than a width W2 of the first aperture OP1A.

Third openings OP3 are formed by removing the first material layers 41 through the first opening OP1. The channel structure CH is exposed through the third openings OP3. Third material layers 43 are formed in the third openings OP3. For example, the third material layers 43 disposed in the third openings OP3 are formed by depositing a third material in the first opening OP1 and the third openings OP3 and etching the third material formed in the first opening OP1. In this example, the third material layer 43 remains in the second aperture OP1B, and the remaining third material layer 43 may be removed.

The third material layers 43 form gate lines and may include metal such as tungsten or molybdenum. The first material layers 41 are replaced with the third material layers 43, and a gate structure GST is formed including the third material layers 43 alternately stacked with the second material layers 42. The third material layers 43 may include a gas. The gas may be a source gas, which may be fluorine gas.

Referring to FIG. 4D, an oxide liner 44 is formed in the first opening OP1. The oxide liner 44 is formed along an inner surface of the gate structure GST adjacent to the first opening OP and is formed at a substantially uniform thickness. A nitride liner 45 is formed on the oxide liner 44. The nitride liner 45 is formed along a surface of the oxide liner 44 and is thicker at an upper end of the first opening OP1 than at a lower end of the first opening OP1.

Referring to FIG. 4E, a first nitride spacer 45A is formed by etching the nitride liner 45. The nitride liner 45 is etched such that the oxide liner 44 is exposed within the first opening OP1. For example, the first aperture OP1A has a narrower width at a lower end than at an upper end, and an end of the nitride liner 45 located at the lower end of the first aperture OP1A may be etched first. Accordingly, the first nitride spacer 45A is formed to avoid covering at least one third material layer 43 located at the lowermost end of the gate structure GST.

A thickness and a height of the first nitride spacer 45A may be adjusted by adjusting an etching time of the nitride liner 45. For example, a section of the nitride liner 45 formed on a bottom surface of the first opening OP1 may be etched by performing a blanket etching process. A section of the nitride liner 45 located at the lower end of the first aperture OP1A may be etched by increasing an etching time of the blanket etching process. The height or length of the first nitride spacer 45A decreases, and the quantity of third material layers 43 not covered by the first nitride spacer 45A increases as the etching time is increased.

When the second aperture OP1B is wider than the first aperture OP1A at the intersection where the first aperture OP1A joins the second aperture OP1B, sections of the nitride liner 45 formed on inner walls of the second portion OP1B are not be etched, and a second nitride spacer 45B is formed in the second aperture OP1B. The first nitride spacer 45A located in the first aperture OP1A and the second nitride spacer 45B located in the second aperture OP1B are spaced apart from each other. The oxide liner 44 is exposed between the first nitride spacer 45A and the second nitride spacer 45B.

An oxide spacer 44A is formed by etching the oxide liner 44. A section of the oxide liner 44 formed on the bottom surface of the first opening OP1 is etched to expose the source structure S. The first aperture OP1A extends into the source structure S. A section of the oxide liner 44 exposed between the first nitride spacer 45A and the second nitride spacer 45B may be etched to a predetermined thickness.

Referring to FIG. 4F, a source contact structure 46 is formed in the first opening OP1. The source contact structure 46 includes a conductive material such as polysilicon or metal. The first nitride spacer 45A surrounds upper sidewalls or an upper end of the source contact structure 46, and the second nitride spacer 45B surrounds lower sidewalls or a lower end of the source contact structure 46. The oxide spacer 44A surrounds the first nitride spacer 45A and the second nitride spacer 45B. For example, the oxide spacer 44A contacts the first nitride spacer 45A and the second nitride spacer 45B and contacts the source contact structure 46 between the first nitride spacer 45A and the second nitride spacer 45B.

Referring to FIG. 4G, an insulating layer 50 and an etch stop layer 51 are formed on or over the gate structure GST. The insulating layer 50 may include oxide, and the etch stop layer 51 may include nitride. Vias 47 and 48 are formed. The via 47 is connected to the channel structure CH, and the via 48 is connected to the source contact structure 46. A hard mask 52 is formed over the etch stop layer 51. The hard mask 52 may be a polysilicon layer and may be formed through a high-temperature process. A hydrogen source layer 53 is formed over the hard mask 52. The hydrogen source layer 53 may be an HDP oxide layer including hydrogen. A hydrogen barrier layer 54 is formed over the hydrogen source layer 53. The hydrogen barrier layer 54 prevents hydrogen diffusion and may be a nitride layer.

A heat treatment process is performed. During the heat treatment process, hydrogen ions H⁺in the hydrogen source layer 53 move into the channel structure CH through the hard mask 52 and the via 47. The hydrogen ions H⁺in the channel structure CH may passivate defects such as a trap in the channel layer 7. Hydrogen ions H⁺in the hydrogen source layer 53 may move into the source contact structure 46 through the hard mask 52 and the via 48. The hydrogen ions H⁺in the source contact structure 46 are diffused away from or without passing through the first nitride spacer 45A. The hydrogen ions H⁺are diffused into the channel structure CH through the oxide spacer 44A at a lower end of the source contact structure 46.

When the high-temperature process that forms the hard mask 52 is performed subsequent to the heat treatment process for hydrogen diffusion, hydrogen passing into the channel structure CH may be diffused again, and a passivation effect may be reduced. According to an embodiment of the present disclosure, by performing the heat treatment process including hydrogen diffusion after forming the hard mask 52, a hydrogen passivation process may be efficiently performed.

During the heat treatment process, the gas in the third material layers 43 is released. The gas in the third material layers 43 is diffused away from or without passing through the first nitride spacer 45A and is diffused into the source contact structure 46 through the oxide spacer 44A.

Referring to FIG. 4H, the hydrogen barrier layer 54 and the hydrogen source layer 53 are removed. An interlayer insulating layer IL and an interconnection structure IC are formed. The interlayer insulating layer IL includes insulating layers 55 and an etch stop layer 56. The insulating layers 55 may be an HDP oxide layer, and the etch stop layer 56 may be a nitride layer. The interconnection structure IC may include a via 57 and/or a wiring line 58. The wiring line 58 connected to the channel structure CH is a bit line. The bit line is formed using the hard mask 52, and the hard mask 52 is removed after the bit line is formed.

By forming the nitride spacers 45A and 45B to surround sections of the sidewalls of the source contact structure 46, a diffusion path for hydrogen and fluorine is established between the first nitride spacer 45A and the second nitride spacer 45B.

During passivation of the channel structure CH, the hydrogen ions H⁺may move into the channel structure through the via 47 and may also move into the source contact structure 46 through the via 48. The hydrogen ions H⁺in the source contact structure 46 may pass through the oxide spacer 44A while avoiding, staying away from, or without passing through the nitride spacers 45A and 45B, and are diffused into the channel structure CH. Accordingly, hydrogen are diffused through various different paths. Hydrogen passivation efficiency may be increased, and cell current and cell distribution may be improved.

The fluorine gas included in the third material layers 43 is released. The fluorine gas in the third material layers 43 passes through the oxide spacer 44A while avoiding or without passing through the first nitride spacer 45A and is diffused into the source contact structure 46. Accordingly, damage to the surrounding layers due to the fluorine gas may be reduced.

Although the detailed embodiments are described in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor device comprising:
a gate structure including a plurality of conductive layers alternately stacked with a plurality of insulating layers;
a source contact structure extending through the gate structure;
a nitride spacer surrounding a first end of the source contact structure; and
an oxide spacer surrounding the nitride spacer and a second end of the source contact structure.

2. The semiconductor device of claim 1, wherein the plurality of conductive layers includes a first set of conductive layers surrounding the first end of the source contact structure and a second set of conductive layers surrounding the second end of the source contact structure, wherein the second set of conductive layers does not surround the nitride spacer and the first set of conductive layers surrounds the nitride spacer.

3. The semiconductor device of claim 2, wherein the first set of conductive layers comprises a drain select line or a word line.

4. The semiconductor device of claim 2, wherein the second set of conductive layers comprises a word line or a source select line.

5. The semiconductor device of claim 1, wherein the oxide spacer contacts an outer wall of the nitride spacer and the second end of the source contact structure.

6. The semiconductor device of claim 1, wherein the nitride spacer has lower gas permeability than the oxide spacer.

7. A semiconductor device comprising:
a source structure;
a gate structure located over the source structure and including a plurality of conductive layers alternately stacked with a plurality of insulating layers;
a source contact structure extending into the source structure through the gate structure;
a first nitride spacer located in the gate structure and surrounding a sidewall of the source contact structure;
a second nitride spacer located within the source structure, surrounding a sidewall of the source contact structure, and spaced apart from the first nitride spacer; and
an oxide spacer extending along the sidewall of the source contact structure and surrounding the first nitride spacer and the second nitride spacer.

8. The semiconductor device of claim 7, wherein the plurality of conductive layers includes a first set of conductive layers located at a first end of the gate structure and a second set of conductive layers located at a second end of the gate structure, wherein the second set of conductive layers does not surround the first nitride spacer, and the first set of conductive layers surrounds the first nitride spacer.

9. The semiconductor device of claim 8, wherein the first set of conductive layers comprises a drain select line or a word line.

10. The semiconductor device of claim 8, wherein the second set of conductive layers comprises a word line or a source select line.

11. The semiconductor device of claim 7, wherein the oxide spacer contacts the source contact structure between the first nitride spacer and the second nitride spacer.

12. The semiconductor device of claim 7, wherein the source contact structure comprises:
a through-segment extending through the gate structure; and
an extension connected to the through-segment and located in the source structure.

13. The semiconductor device of claim 12, wherein the extension is wider than the through-segment.

14. The semiconductor device of claim 12, wherein the second nitride spacer surrounds the extension.

15. The semiconductor device of claim 7, wherein the first nitride spacer has a tapered shape.

16. The semiconductor device of claim 7, further comprising a channel structure extending through the gate structure and connected to the source structure.

17. A method of manufacturing a semiconductor device, the method comprising:
forming a stack including a plurality of first material layers alternately stacked with a plurality of second material layers;
forming an opening extending through the stack;
forming an oxide liner within the opening;
forming a nitride liner along a surface of the oxide liner;
forming a nitride spacer by etching the nitride liner such that the oxide liner is partially exposed;
forming an oxide spacer by etching the oxide liner, the oxide spacer extending along the inner wall of the stack and surrounding the nitride spacer; and
forming a source contact structure within the nitride spacer and the oxide spacer.

18. The method of claim 17, wherein the nitride spacer surrounds a first end of the source contact structure, and the oxide spacer surrounds the nitride spacer and a second end of the source contact structure.

19. The method of claim 17, wherein the nitride liner is formed along a surface of the oxide liner and has a tapered shape.

20. The method of claim 17, wherein the opening has a tapered shape.

21. The method of claim 17, further comprising replacing the first material layers with third material layers.

22. The method of claim 21, further comprising releasing a gas in the third material layers to the source contact structure through the oxide spacer.

23. The method of claim 22, wherein the gas includes a fluorine gas.

24. The method of claim 22, wherein the nitride spacer is a diffusion barrier.

25. A method of manufacturing a semiconductor device, the method comprising:
forming a stack over a source structure;
forming an opening extending into the source structure through the stack;
forming an oxide liner within the opening;
forming a nitride liner along a surface of the oxide liner;
forming a first nitride spacer and a second nitride spacer by etching the nitride liner, the second nitride spacer located in the source structure and spaced apart from the first nitride spacer; and
forming an oxide spacer by etching the oxide liner, the oxide spacer surrounding the first nitride spacer and the second nitride spacer.

26. The method of claim 25, further comprising forming a source contact structure within the first nitride spacer, the second nitride space, and the oxide spacer.

27. The method of claim 26, wherein the first nitride spacer surrounds a first end of the source contact structure, and
the second nitride spacer surrounds a second end of the source contact structure.

28. The method of claim 26, wherein the oxide spacer contacts the source contact structure between the first nitride spacer and the second nitride spacer.

29. The method of claim 26, wherein the source contact structure includes a fluorine gas.

30. The method of claim 26, further comprising:
forming a channel structure extending into the source structure through the stack;
forming a hydrogen source layer over the stack; and
performing an annealing process.

31. The method of claim 30, wherein, when the annealing process is performed, hydrogen is supplied to the channel structure through the hydrogen source layer, the source contact structure, and the oxide spacer.

32. The method of claim 25, wherein the opening has a first width inside the stack and is wider than the first width inside the source structure.

33. The method of claim 25, wherein the first nitride spacer is a diffusion barrier.

34. The method of claim 25, wherein the opening comprises:
a first aperture located inside the stack; and
a second aperture located inside the source structure, and a width of the second aperture is wider than the width of the first aperture where the first aperture and the second aperture meet.

35. The method of claim 34, wherein the first nitride spacer is formed in the first aperture, and the second nitride spacer is formed in the second aperture.
